(19) United States
(12) Patent Application Publication
(10) Pub. No.: US 2007/0034355 A1
(43) Pub. Date: Feb. 15, 2007

(54) HEAT-DISSIPATION STRUCTURE AND METHOD THEREOF

(75) Inventor: Ming-Chien Kuo, Taipei Hsien (TW)

Correspondence Address: J C PATENTS, INC., 4 VENTURE, SUITE 250, IRVINE, CA, 92618, US

(73) Assignee: COOLER MASTER CO.,LTD., Taipei Hsien (TW)

(21) Appl. No.: 11/462,461

(22) Filed: Aug. 4, 2006

(30) Foreign Application Priority Data
Aug. 10, 2005 (TW) 94127117

(51) Int. Cl. H05K 7/20

(52) U.S. Cl. 165/80.4; 165/104.33; 361/699; 165/104.14

(57) ABSTRACT

A heat-dissipation structure mainly including a heat-absorbing head, a heat pipe, and a tube jacket is provided. The heat pipe includes a heated end and a cooling end, wherein the heated end of the heat pipe is connected to the heat-absorbing head, and a flange is projected form the surface of the heat pipe adjacent to the cooling end. A joint is disposed on the cooling end of the heat pipe, and is connected to the tube jacket through the opening, such that the cooling end is sealed inside the tube jacket, and the flange of the heat pipe is tightly fastened between the joint and the opening. The heat-dissipation structure is used to rapidly conduct the waste heat generated by a processing chip to the tube jacket via the heat pipe.

### CROSS-REFERENCE TO RELATED APPLICATION

This application claims the priority benefit of Taiwan application serial no. 94127117, filed on Aug. 10, 2005. All disclosure of the Taiwan application is incorporated herein by reference.

### BACKGROUND OF THE INVENTION

1. Field of the Invention

The present invention relates to a heat-dissipation structure, and more particularly to a heat-dissipation structure applicable to an electronic device.

2. Description of Related Art

With the progress of semiconductor technology, integrated circuits (ICs) have been largely used in chips of an electronic device such as a personal computer, a PC notebook, and a network server. However, as the processing speed and function of the ICs are significantly increased, the waste heat generated by the IC also correspondingly increases significantly, and if the waste heat cannot be effectively dissipated, the electronic device failure occurs. Therefore, various heat-dissipation methods are proposed to rapidly dissipate the waste heat generated by the ICs, so as to avoid the electronic device failure.

FIG. 1 is a schematic side view of a conventional air-cooling heat-dissipation device. Referring to FIG. 1, a conventional heat-dissipation device 100 can dissipate the waste heat generated by a central processing unit (CPU) 52 on a mainboard 50. The heat-dissipation device 100 is locked on the mainboard 50 by screws 110, such that the lower edge of the heat-dissipation device 100 is attached to the upper edge of the CPU 52. The waste heat generated by the CPU 52 when operating can be conducted from the upper edge of the CPU 52 to the heat-dissipation device 100, and then is dissipated to the air via the heat-dissipation device 100. In order to increase the contact area between the heat-dissipation device 100 and the air, a plurality of heat-dissipation fins 120 are usually disposed on the heat-dissipation device 100. Meanwhile, in order to increase air turbulence, a heat-dissipation fan 130 can be further disposed above the heat-dissipation device 100, thereby increasing the heat-dissipation rate of the heat-dissipation device 100 to dissipate heat to the air.

Accordingly, the thermal conductivity between the heat-dissipation device 100 and the air depends on the contact area therebetween and the value of air turbulence. Thus, when the CPU 52 generates more waste heat due to the improved performance, the heat-dissipation device 100 must correspondingly have more heat-dissipation fins 120 or accelerate the rotation rate of the heat-dissipation fan 130, so as to dissipate the waste heat generated by the CPU 52 to the air. However, the volume of the heat-dissipation device 100 must be increased to accommodate more heat-dissipation fins 120, which increases the manufacturing cost of the heat-dissipation device 100, and the weight of the heat-dissipation device 100 on the CPU 52 may easily damage the CPU 52. Moreover, the noise caused by the increased rotation rate of the heat-dissipation fan 130 cannot meet the low noise requirement in use.

In order to solve the problems of the heat-dissipation device such as poor heat-dissipation performance, conventionally, a design of circulation flow of water for dissipating heat is proposed. FIG. 2 is a schematic side view of a conventional water-cooling heat-dissipation device. Referring to FIG. 2, a conventional heat-dissipation device 200 dissipates the waste heat generated by the CPU 52 on the mainboard 50. The heat-dissipation device 200 has a channel 210 inside for water to pass there-through, and two ends of the channel 210 have a water inlet 212 and a water outlet 214 respectively connected to a water-cooling pipe 220. When the water flows into the channel 210 in the heat-dissipation device 200 from the water inlet 212, the water absorbs the waste heat generated by the CPU 52, and then flows out from the water outlet 214 so that the waste heat is dissipated. The water has a high specific heat, and therefore can absorb the heat significantly. Thus, the heat-dissipation device 200 has an effect of rapid heat-dissipation. However, high-tech CPU 52 and mainboard 50 are disposed below the heat-dissipation device 200, and if the heat-dissipation device 200 is not completely sealed, the water leaks from the seal, thus resulting in a short circuit and damage the CPU 52 or the mainboard 50.

### SUMMARY OF THE INVENTION

Accordingly, an objective of the present invention is to provide a heat-dissipation structure having the effect of rapid heat dissipation.

Another objective of the present invention is to provide a water-cooling heat-dissipation structure, which is used to rapidly dissipate the waste heat generated by a processing chip.

Still another objective of the present invention is to provide a water-cooling heat-dissipation method, which can achieve the purpose of rapid heat dissipation.

Based on the above and other objectives, the present invention provides a heat-dissipation structure, which at least comprises a heat-absorbing head, a heat pipe, and a tube jacket. The first end (heated end) of the heat pipe is connected to the heat-absorbing head. A joint is disposed on the second end (cooling end) of the heat pipe, and a flange is projected from the surface of the heat pipe adjacent to the second end. The tube jacket at least comprises a water inlet, a water outlet, and an opening for mounting, wherein the opening is connected to the joint, such that the second end of the heat pipe is sealed inside the tube jacket, and the flange of the heat pipe is tightly fastened between the opening and the joint.

In an embodiment of the present invention, the heat-dissipation structure further comprises a first seal ring and/or a second seal ring, wherein the first seal ring is disposed between the flange and the opening, and the second seal ring is disposed between the flange and the joint.

In an embodiment of the present invention, the opening and the joint are interlocked by, for example, a thread structure. The thread structure may comprise an internal thread disposed on the joint and an external thread disposed on the opening.

In an embodiment of the present invention, a waterproof tape is wound, for example, around the opening.

Based on the above and other objectives, the present invention further provides a water-cooling heat-dissipation structure, which is suitable for dissipating heat generated by a processing chip of an electronic device. The heat-dissipation structure at least comprises a heat-absorbing head, a heat pipe, a tube jacket, a first pipe, and a second pipe. The heat-absorbing head is thermally connected to the processing chip, and the first end (heated end) of the heat pipe is connected to the heat-absorbing head. A joint is disposed on the second end (cooling end) of the heat pipe, and a flange is projected from the surface of the heat pipe adjacent to the second end. The tube jacket at least comprises a water inlet, a water outlet, and an opening for mounting, wherein the joint is connected to the tube jacket through the opening, the second end of the heat pipe is sealed inside the tube jacket, and the flange of the heat pipe is tightly fastened between the opening and the joint. One end of the first pipe is connected to the water outlet of the tube jacket, and the other end is connected to a water inlet of a water-cooler. One end of the second pipe is connected to the water inlet of the tube jacket, and the other end is connected to a water outlet of the water-cooler.

In an embodiment of the present invention, the water-cooling heat-dissipation structure further comprises a first seal ring and/or a second seal ring, wherein the first seal ring is disposed between the flange and the opening, and the second seal ring is disposed between the flange and the joint.

In an embodiment of the present invention, the opening and the joint are interlocked by, for example, a thread structure. The thread structure may comprise an internal thread disposed on the joint and an external thread disposed on the opening.

In an embodiment of the present invention, the water-cooler comprises a plurality of water-cooling plates.

In an embodiment of the present invention, a waterproof tape is wound around the opening.

In an embodiment of the present invention, the water-cooling heat-dissipation structure further comprises, for example, a pump connected between the first pipe and the second pipe.

Based on the above and other objectives, the present invention further provides a water-cooling heat-dissipation method, which at least comprises providing a heat pipe, a tube jacket, and a heat-dissipation head. The first end (heated end) of the heat pipe is connected to the heat-absorbing head. A joint is disposed on the second end (cooling end) of the heat pipe, and a flange is projected from the surface of the heat pipe adjacent to the second end. The tube jacket at least comprises a water inlet, a water outlet, and an opening for mounting, wherein the joint is connected to the tube jacket through the opening, such that the second end of the heat pipe is sealed inside the tube jacket, and the flange of the heat pipe is tightly fastened between the opening and the joint. One end of a first pipe is disposed on the water outlet of the tube jacket, and one end of a second pipe is connected to the water inlet of the tube jacket. A water-cooling liquid flows into the tube jacket via the water inlet, and exchanges heat with the second end of the heat pipe, and then flows out via the water outlet of the tube jacket.

In an embodiment of the present invention, the method further comprises, for example, making the water-cooling liquid flow into a water-cooler via the other end of the first pipe, so as to perform refrigeration and heat-dissipation. Further, for example, the water-cooling liquid flows into the second pipe via a water outlet of the water-cooler.

In an embodiment of the present invention, the water-cooler comprises, for example, a plurality of water-cooling plates.

In an embodiment of the present invention, the method further comprises, disposing a first seal ring between the flange and the opening.

In an embodiment of the present invention, the method further comprises disposing a second seal ring between the flange and the joint.

In an embodiment of the present invention, the method further comprises disposing a first seal ring between the flange and the opening, and disposing a second seal ring between the flange and the joint.

In an embodiment of the present invention, the method further comprises winding a waterproof tape around the opening.

To sum up, the heat-dissipation structure of the present invention is mainly used to rapidly conduct the waste heat generated by the processing chip to the tube jacket via the heat pipe, and then dissipate the waste heat conducted to the tube jacket via the fluid (water-cooling liquid) circulation flow. As such, the heat-dissipation performance of the heat-dissipation structure can be improved, and the space for distributing heat-dissipation components on the processing chip can be reduced.

In order to make the aforementioned and other objects, features and advantages of the present invention comprehensible, preferred embodiments accompanied with figures are described in detail below.

### BRIEF DESCRIPTION OF THE DRAWINGS

FIG. 1 is a schematic side view of a conventional air-cooling heat-dissipation device.

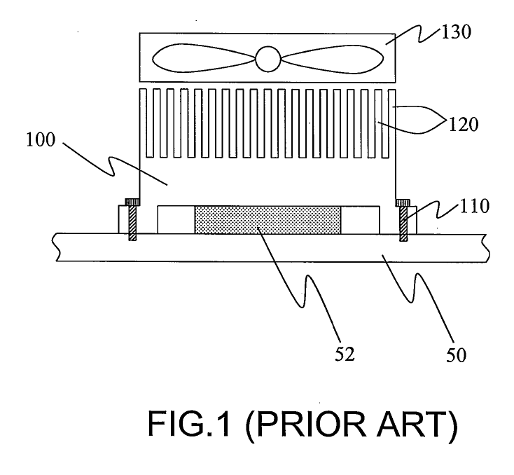

FIG. 2 is a schematic side view of a conventional water-cooling heat-dissipation device.

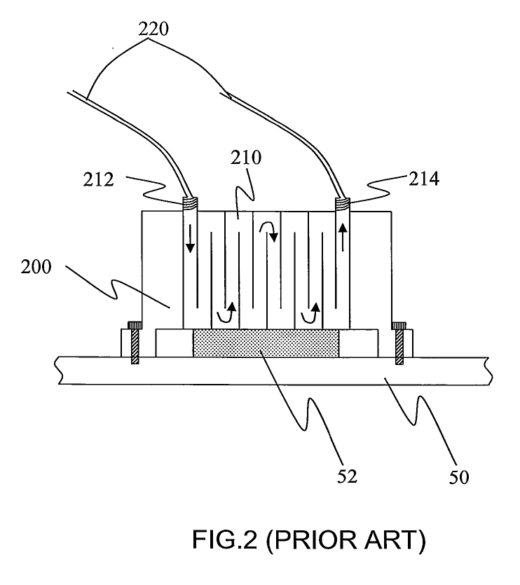

FIG. 3A is a schematic exploded view of components of a heat-dissipation structure according to an embodiment of the present invention.

FIG. 3B is an assembled schematic view of FIG. 3A.

FIG. 4A is a schematic sectional view of the heat pipe of FIG. 3A.

FIG. 4B is a schematic partial sectional view of FIG. 3B.

FIG. 5 is a schematic sectional view of the heat-dissipation structure disposed on an electronic device according to the present invention.

### DESCRIPTION OF EMBODIMENTS

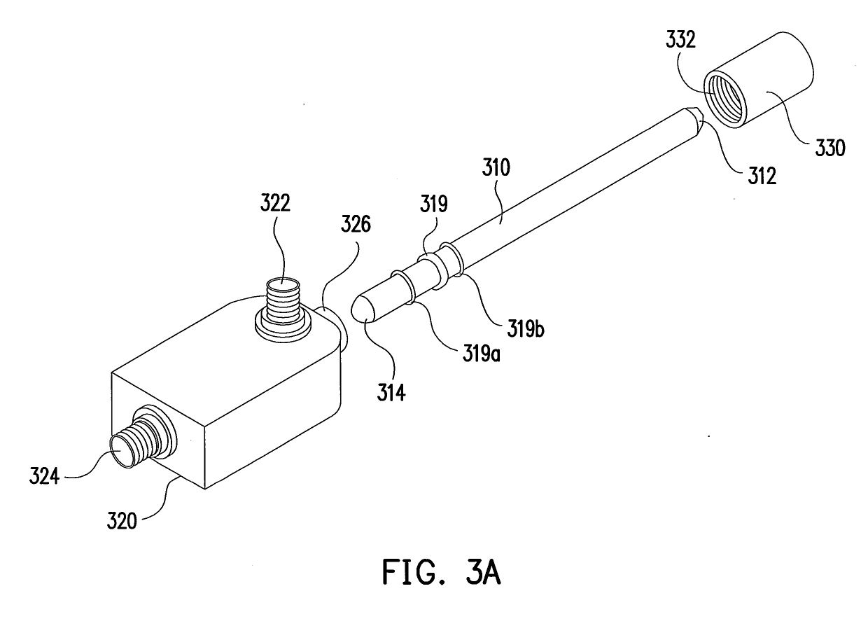

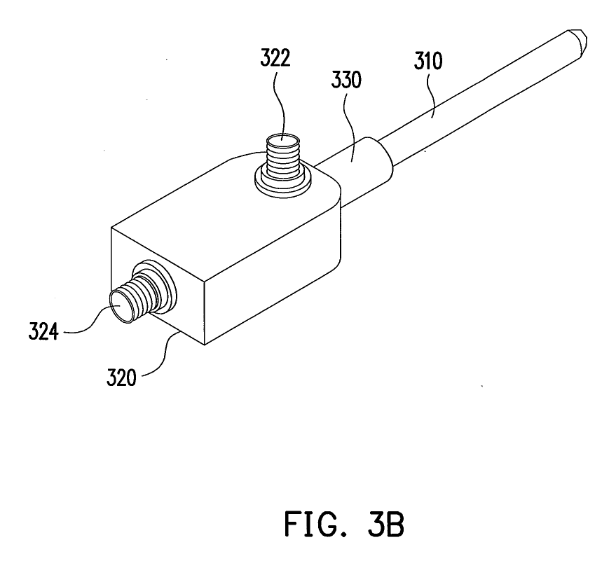

FIG. 3A is a schematic exploded view of components of a heat-dissipation structure according to an embodiment of the present invention. Referring to FIG. 3A, the heat-dissipation method of the present embodiment mainly comprises conducting heat to a tube jacket 320 via a heat pipe 310, and dissipating the heat by circulation flow of fluid in the tube jacket 320. Moreover, the heat pipe 310 is connected to the tube jacket 320 via a joint 330, as shown in FIG. 3B. Since the heat pipe 310 is an important feature of the present invention, the structure of the heat pipe 310 is illustrated in detail in accompany with the figure below.

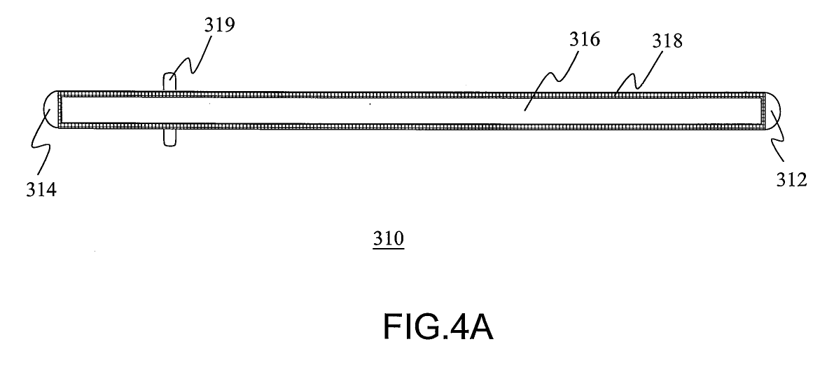

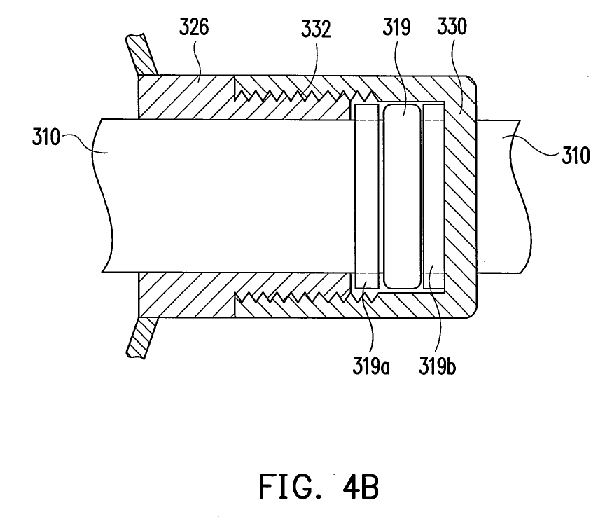

FIG. 4A is a schematic sectional view of the heat pipe of FIG. 3A. Referring to FIG. 4A, the heat pipe 310 comprises a heated end 312 (first end) and a cooling end 314 (second end). When a temperature difference exists between the heated end 312 and the cooling end 314, the heat pipe 310 rapidly conducts the heat of the heated end 312 to the cooling end 314 to achieve the effect of heat-dissipation. In the present embodiment, the heat-dissipation method of the heat pipe 310 is provided by first pumping an inner cavity 316 of the heat pipe 310 into a negative pressure state, and filling a working fluid (not shown) in the inner cavity 316. An inner wall 318 of the heat pipe 310 can be a capillary structure (e.g., metal mesh structure) or constituted of capillary porous material. When the heated end 312 is heated, the working fluid in the inner cavity 316 adjacent to the heated end 312 is evaporated into vapor (not shown), and the vapor rapidly flows to the cooling end 314 under an appreciable pressure difference, and releases heat to be condensed into the working fluid. Then, the working fluid, under the capillary force, flows back to the heated end 312 along the inner wall 318 of the heat pipe 310. As such, keep the circulation going, such that the heat can be rapidly conducted from the heated end 312 of the heat pipe 310 to the cooling end 314, so as to achieve the heat-dissipation effect.

In view of the above, the material of the heat pipe 310 comprises, for example, aluminum, copper, or another metal or alloy of high thermal conductivity coefficient, and the working fluid can be water or another volatile substance with high specific heat. However, the arrangement of the internal components of the heat pipe 310 is not limited to the above manner, for example, the heat pipe 310 can also be a loop heat pipe (LHP) or two-phase flow capillary pump loop (CPL) heat pipe, and the arrangement of the internal components of the heat pipe 310 is not limited in the present invention.

Moreover, in order to achieve the easy-to-assemble and easy-to-position of the heat pipe 310 and other components of the heat-dissipation structure, in the present embodiment, a flange 319 is further projected from the surface of the heat pipe 310 adjacent to the cooling end 314, and the flange 319 can be formed by internal-processing or by soldering a ring.

Referring to FIG. 3A again, the tube jacket 320 has a water inlet 322, a water outlet 324, and an opening for mounting 326 corresponding to the joint 330. The interior of the tube jacket 320 is the place where the fluid (not shown) exchanges heat with the heat pipe 310. In the present embodiment, the tube jacket 320 has a function of allowing a fluid flowing into the tube jacket 320 via the water inlet 322 to absorb the waste heat conducted by the cooling end 314 of the heat pipe 310 and then the fluid flows out from the tube jacket 320 via the water outlet 324 to take the heat away, thus achieving the effect of heat-dissipation. In the present embodiment, the fluid is, for example, water-cooling liquid, or another substance with high specific heat.

FIG. 3B is an assembled schematic view of FIG. 3A. Referring to FIG. 3A and FIG. 3B together, the cooling end 314 of the heat pipe 310 is inserted into the tube jacket 320 from the opening 326, such that the flange 319 of the heat pipe 310 presses against the opening 326. Then, the joint 330 is disposed on the cooling end 314 from the heated end 312 of the heat pipe 310 to be locked with the opening 326. In the present embodiment, the joint 330 has an internal thread 332, and the opening 326 has an external thread (not shown) corresponding to the internal thread 332. The internal thread 332 and the external thread form a thread structure, such that when the joint 330 is screwed with the opening 326, the joint 330 and the opening 326 may be tightly interlocked, so as to prevent the leakage of the fluid in the tube jacket 320. However, the joining maimer of the joint 330 and the opening 326 is not limited in the present invention. For example, a waterproof tape can be wound on the opening 326, and then the joint 330 and the opening 326 are joined to prevent the fluid in the tube jacket 320 from leaking through the joint 330. Moreover, in order to enhance the assembly of the heat pipe 310 and tube jacket 320, a first seal ring 319a and a second seal ring 319b can be respectively disposed on both sides of the flange 319 of the heat pipe 310. The first seal ring 319a and the second seal ring 319b are, for example, waterproof O-shaped rings.

FIG. 4B is a schematic partial sectional view of FIG. 3B. Referring to FIG. 3B and FIG. 4B together, when the joint 330 is screwed with the opening 326, the flange 319 of the heat pipe 310 is joint with the inner wall of the joint 330, so as to prevent the fluid in the tube jacket 320 from leaking through the joint 330. In addition, the flange 319 also prevents the smooth heat pipe 310 from freely sliding. Further, the first seal ring 319a is disposed between the flange 319 and the opening 326, and the second seal ring 319b is disposed between the flange 319 and the joint 330, thereby enhancing the assembly of the joint 330, the heat pipe 310, and the opening 326 therebetween. In addition, the first seal ring 319a can be used as a buffer material between the flange 319 and the opening 326, and the second seal ring 319b can be used as a buffer material between the flange 319 and the joint 330, thereby protecting the flange 319 from being deformed and damaged by the direct pressing of the joint 330 or the opening 326 during the assembling.

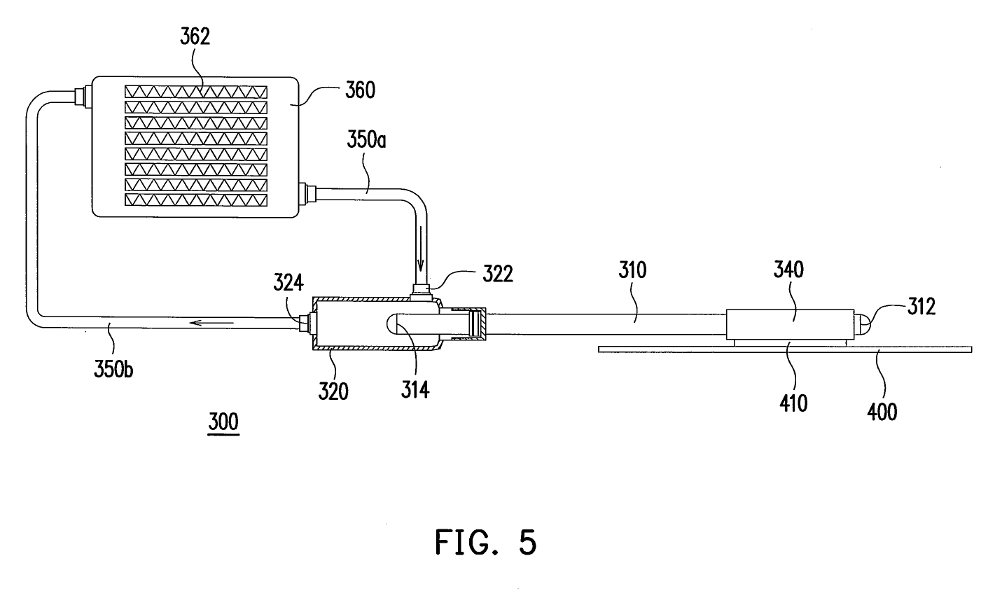

FIG. 5 is a schematic sectional view of the heat-dissipation structure disposed on an electronic device according to the present invention. Referring to FIG. 5, the heat pipe 310 is inserted in a heat-absorbing head 340 with the heated end 312 thereof, such that the heat-absorbing head 340 is connected to the heat pipe 310 and adjacent to the heated end 312. In FIG. 5, only one heat pipe 310 is shown; however, the number of the heat pipe 310 can be increased or reduced according to the required heat-dissipation efficiency. Moreover, the heat-absorbing head 340 is disposed on a processing chip 410 of an electronic device 400, and the heat-absorbing head 340 is suitable for receiving the waste heat generated by the processing chip 410, and conducting the waste heat to the heat pipe 310. The material of the heat-absorbing head 340 comprises, for example, aluminum, copper, or another metal or alloy of high thermal conductivity coefficient. The electronic device 400 is, for example, mainboard, circuit board, and the like, and the processing chip 410 is, for example, a heat source of CPU, chip set, or power electronic device and the like. However, the material of the heat-absorbing head 340 and the types of the electronic device 400 and the processing chip 410 are not limited in the present invention.

In view of the above, the heat-dissipation structure 300 of the present embodiment further comprises two pipes 350a, 350b, wherein one end of the pipe 350a and one end of the pipe 350b are respectively connected to the water inlet 322 and water outlet 324 of the tube jacket 320, and the other ends of the pipes 350a, 350b are respectively connected to a water-cooler 360. As such, the fluid can circulate between the tube jacket 320 and the water-cooler 360 by a pump (not shown). When the fluid absorbing the heat flows out from the water outlet 324, it can flow into the water-cooler 360 via the pipe 350b to release heat, and then flow into the tube jacket 320 from the water inlet 322 via the pipe 350a to absorb heat of the heat pipe 310 again. As such, keep the circulation going, and the effect of heat-dissipation can be achieved. In the present embodiment, the water-cooler 360 comprises, for example, a plurality of water-cooling plates 362, so as to increase the contact area between the water-cooler 360 and the fluid to improve the heat-dissipation efficiency. Moreover, the water-cooler 360 dissipates heat by, for example, refrigeration and compression to lower the temperature. However, the heat-dissipation method of the water-cooler 360 is not limited in the present invention.

The heat-dissipation methods of above various components are integrated below to clearly disclose the heat-dissipation method of the heat-dissipation structure 300 according to the present embodiment. Referring to FIG. 5 again, after the electronic device 400 is activated, the waste heat generated by the operating of the processing chip 410 is rapidly conducted to the heat pipe 310 via the heat-absorbing head 340, such that a temperature difference is generated between the heated end 312 and the cooling end 314 of the heat pipe 310. The heat pipe 310 can rapidly transmit the heat from the heated end 312 to the cooling end 314 by the working fluid. It should be noted that since the heat-dissipation efficiency of the heat pipe 310 is very high, and the heat-dissipation effect of the heat-dissipation structure 300 can be significantly improved. Then, the fluid in the tube jacket 320 absorbs the waste heat in the cooling end 314, and carries the waste heat to the water-cooler 360 in a manner of circulation flow and then dissipates the waste heat, and thus the whole process of heat-dissipation is complete. In addition, as the tube jacket 320 is not directly disposed over the processing chip 410, the available space above the processing chip 410 can be significantly increased, and when the fluid leaks from tube jacket 320, the processing chip 410 or the electronic device 400 will not be influenced.

To sum up, in the heat-dissipation structure of the present invention, the heat pipe is used to rapidly conduct the waste heat generated by the processing chip to the fluid in the tube jacket. The design of flange of the heat pipe enhances the performance of tightly fastening the opening and joint of the tube jacket, and preventing water leaking. The waste heat is dissipated by the circulation flow of fluid. As such, the heat-dissipation effect of the heat-dissipation structure can be improved, and the available space above the processing chip can be increased.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A heat-dissipation structure, comprising:
a heat-absorbing head;
at least one heat pipe, having a first end and a second end, wherein the first end is connected to the heat-absorbing head, a joint is disposed on the second end, and a flange is projected from the surface of the heat pipe adjacent to the second end; and
at least one tube jacket, having at least one water inlet, at least one water outlet, and at least one opening for mounting, wherein the joint is connected to the tube jacket through the opening, the second end of the heat pipe is sealed inside the tube jacket, and the flange of the heat pipe is tightly fastened between the opening and the joint.

2. The heat-dissipation structure as claimed in claim 1, further comprising a first seal ring disposed between the flange and the opening.

3. The heat-dissipation structure as claimed in claim 1, further comprising a second seal ring disposed between the flange and the joint.

4. The heat-dissipation structure as claimed in claim 1, further comprising a first seal ring disposed between the flange and the opening, and a second seal ring disposed between the flange and the joint.

5. The heat-dissipation structure as claimed in claim 1, wherein the opening and the joint are interlocked by a thread structure.

6. The heat-dissipation structure as claimed in claim 5, wherein the thread structure comprises an internal thread and an external thread, respectively disposed on the joint and the opening.

7. The heat-dissipation structure as claimed in claim 1, wherein a waterproof tape is wound around the opening.

8. A water-cooling heat-dissipation structure, suitable for an electronic device having a processing chip, the heat-dissipation structure comprises:
a heat-absorbing head, thermal connected to the processing chip;
at least one heat pipe, having a first end and a second end, wherein the first end is connected to the heat-absorbing head, a joint is disposed on the second end, and a flange is projected from the surface of the heat pipe adjacent to the second end;
at least one tube jacket, having at least one water inlet, at least one water outlet, and at least one opening for mounting, wherein the joint is connected to the tube jacket through the opening, the second end of the heat pipe is sealed inside the tube jacket, and the flange of the heat pipe is tightly fastened between the opening and the joint;
at least one first pipe, having one end connected to the water outlet of the tube jacket, and the other end connected to a water inlet of a water-cooler; and
at least one second pipe, having one end connected to the water inlet of the tube jacket, and the other end connected to a water outlet of the water-cooler.

9. The water-cooling heat-dissipation structure as claimed in claim 8, further comprising a first seal ring disposed between the flange and the opening.

10. The water-cooling heat-dissipation structure as claimed in claim 8, further comprising a second seal ring disposed between the flange and the joint.

11. The water-cooling heat-dissipation structure as claimed in claim 8, further comprising a first seal ring disposed between the flange and the opening, and a second seal ring disposed between the flange and the joint.

12. The water-cooling heat-dissipation structure as claimed in claim 8, wherein the opening and the joint are interlocked by a thread structure.

13. The water-cooling heat-dissipation structure as claimed in claim 12, wherein the thread structure comprises an internal thread and an external thread, respectively disposed on the joint and the opening.

14. The water-cooling heat-dissipation structure as claimed in claim 8, wherein the water-cooler comprises a plurality of water-cooling plates.

15. The water-cooling heat-dissipation structure as claimed in claim 8, wherein a waterproof tape is wound around the opening.

16. The water-cooling heat-dissipation structure as claimed in claim 8, further comprising a pump connected between the first pipe and the second pipe.

17. A water-cooling heat-dissipation method, comprising:
providing at least one heat pipe having a first end and a second end, wherein a flange is projected from the surface of the heat pipe adjacent the second end;
disposing a heat-absorbing head on the first end;
disposing a tube jacket on the second end, wherein the tube jacket has at least one water inlet, at least one water outlet, and at least one opening;
disposing a joint on the tube jacket through the opening, sealing the second end of the heat pipe inside the tube jacket, and tightly fastening the flange of the heat pipe between the opening and the joint;
disposing one end of a first pipe on the water outlet of the tube jacket;
connecting one end of a second pipe to the water inlet of the tube jacket; and
making a water-cooling liquid flow into the tube jacket via the water inlet, and the water-cooling liquid exchanges heat with the second end of the heat pipe, and flows out via the water outlet of the tube jacket.

18. The water-cooling heat-dissipation method as claimed in claim 17, further comprising making the water-cooling liquid flow into a water-cooler via the other end of the first pipe, so as to perform refrigeration and heat-dissipation.

19. The water-cooling heat-dissipation method as claimed in claim 18, further comprising making the water-cooling liquid flow into the second pipe via a water outlet of the water-cooler.

20. The water-cooling heat-dissipation method as claimed in claim 18, wherein the water-cooler comprises a plurality of water-cooling plates.

21. The water-cooling heat-dissipation method as claimed in claim 17, wherein the step of disposing the tube jacket on the second end further comprises disposing a first seal ring between the flange and the opening.

22. The water-cooling heat-dissipation method as claimed in claim 17, wherein the step of disposing the joint on the tube jacket through the opening further comprises disposing a second seal ring between the flange and the joint.

23. The water-cooling heat-dissipation method as claimed in claim 17, wherein the step of disposing the tube jacket on the second end further comprises disposing a first seal ring between the flange and the opening, and the step of disposing the joint on the tube jacket through the opening further comprises disposing a second seal ring between the flange and the joint.

24. The water-cooling heat-dissipation method as claimed in claim 17, wherein the step of disposing the joint on the tube jacket through the opening further comprises winding a waterproof tape around the opening.
